(19) United States
(12) Patent Application Publication
(10) Pub. No.: US 2026/0143663 A1
(43) Pub. Date: May 21, 2026

(54) VERTICAL STATIC RANDOM-ACCESS MEMORY WITH STACKED FIELD-EFFECT TRANSISTOR

(71) Applicant: International Business Machines Corporation, Armonk, NY (US)

(72) Inventors: Govind Bajpai, Albany, NY (US); Sushant Kumar, East Greenbush, NY (US); Trevor McDonough, Halfmoon, NY (US); Anthony I-Chih Chou, Guilderland, NY (US); Ruilong Xie, Niskayuna, NY (US); Carl Radens, LaGrangeville, NY (US)

(21) Appl. No.: 18/952,554

(22) Filed: Nov. 19, 2024

(51) Int. Cl. H10B 10/00

(52) U.S. Cl. CPC H10B 10/125

(57) ABSTRACT

A semiconductor structure includes a first transistor device disposed on a substrate, the first transistor device having a first orientation, and a second transistor device disposed on the first transistor device in a stacked configuration, the second transistor device having a second orientation different than the first orientation.

### BACKGROUND

Static random-access memory (SRAM) may be used, for example, to temporarily store data in a computer system. An SRAM device includes an array of bitcells in which each bitcell retains a single bit of data during operation and is able to be programmed with a value for the single bit. Each SRAM bitcell may have a 6-transistor (6T) design that includes a pair of cross-coupled inverters and a pair of access transistors connecting the inverters to complementary bit lines. The two access transistors are controlled by word lines, which are used to select the SRAM memory cell for read or write operations. When continuously powered, the memory state of an SRAM persists without the need for data refresh operations.

### SUMMARY

Illustrative embodiments of the present application include techniques for use in semiconductor manufacture. In an illustrative embodiment, a semiconductor structure includes a first transistor device disposed on a substrate, the first transistor device having a first orientation, and a second transistor device disposed on the first transistor device in a stacked configuration, the second transistor device having a second orientation different than the first orientation.

In another illustrative embodiment, a semiconductor structure includes a first transistor device disposed on a substrate, the first transistor device including a first source/drain region and frontside source/drain region contact, the first transistor device having a first orientation. The semiconductor structure further includes a second transistor device disposed on the first transistor device in a stacked configuration, the second transistor device including a first transistor structure including a gate structure and a second transistor structure including a second source/drain region. The semiconductor structure further includes a first straight metal via connecting the frontside source/drain region contact of the first transistor device to the gate structure, and a second straight metal via connecting the frontside source/drain region contact of the first transistor device to the second source/drain region. The second transistor device has a second orientation different than the first orientation.

In yet another illustrative embodiment, an integrated circuit includes one or more semiconductor structures. At least one of the one or more semiconductor structures is a semiconductor structure according to one or more of the foregoing illustrative embodiments.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1A is a top-down view illustrating a semiconductor structure during an intermediate step of a method of fabricating a first transistor structure, according to an illustrative embodiment.

FIG. 1B is a cross-sectional view of the semiconductor structure taken along the X-X axis of FIG. 1A during the intermediate step, according to an illustrative embodiment.

FIG. 1C is a cross-sectional view of a semiconductor structure taken along the Y-Y axis of FIG. 1A during the intermediate step, according to an illustrative embodiment.

FIG. 2A is a cross-sectional view of the semiconductor structure taken along the X-X axis of FIG. 1A following formation of a second transistor structure, according to an illustrative embodiment.

FIG. 2B is a cross-sectional view of the semiconductor structure taken along the Y-Y axis of FIG. 1A following formation of the second transistor structure, according to an illustrative embodiment.

FIG. 3A is a cross-sectional view of the semiconductor structure taken along the X-X axis of FIG. 1A following formation of a third transistor structure, according to an illustrative embodiment.

FIG. 3B is a cross-sectional view of the semiconductor structure taken along the Y-Y axis of FIG. 1A following formation of the third transistor structure, according to an illustrative embodiment.

FIG. 4A is a cross-sectional view of the semiconductor structure taken along the X-X axis of FIG. 1A following formation of frontside contacts, a back-end-of-the-line interconnect and a carrier wafer, according to an illustrative embodiment.

FIG. 4B is a cross-sectional view of the semiconductor structure taken along the Y-Y axis of FIG. 1A following formation of the frontside contacts, the back-end-of-the-line interconnect and the carrier wafer, according to an illustrative embodiment.

FIG. 5A is a cross-sectional view of the semiconductor structure taken along the X-X axis of FIG. 1A following flipping the carrier wafer and backside substrate removal, according to an illustrative embodiment.

FIG. 5B is a cross-sectional view of the semiconductor structure taken along the Y-Y axis of FIG. 1A following flipping the carrier wafer and the backside substrate removal, according to an illustrative embodiment.

FIG. 6A is a cross-sectional view of the semiconductor structure taken along the X-X axis of FIG. 1A following etch stop layer and remaining substrate removal, followed by formation of an interlevel dielectric (ILD) layer, according to an illustrative embodiment.

FIG. 6B is a cross-sectional view of the semiconductor structure taken along the Y-Y axis of FIG. 1A following the etch stop layer and remaining substrate removal, followed by formation of the ILD layer, according to an illustrative embodiment.

FIG. 7A is a cross-sectional view of the semiconductor structure taken along the X-X axis of FIG. 1A following sacrificial placeholder removal, followed by formation of a backside contact, according to an illustrative embodiment.

FIG. 7B is a cross-sectional view of the semiconductor structure taken along the Y-Y axis of FIG. 1A following the sacrificial placeholder removal, followed by formation of the backside contact, according to an illustrative embodiment.

FIG. 8A is a cross-sectional view of the semiconductor structure taken along the X-X axis of FIG. 1A following formation of a backside interconnect, according to an illustrative embodiment.

FIG. 8B is a cross-sectional view of the semiconductor structure taken along the Y-Y axis of FIG. 1A following formation of the backside interconnect, according to an illustrative embodiment.

FIG. 9 depicts a circuit diagram of the semiconductor structure, according to an illustrative embodiment.

### DETAILED DESCRIPTION

Various illustrative embodiments of the invention may be described herein in the context of illustrative methods for forming a vertical static random-access memory (SRAM), and more particularly to a stacked vertical field-effect transistor structure, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

Detailed embodiments of the semiconductor structures and methods are disclosed herein. The method steps described below do not form a complete process flow for manufacturing integrated circuits, such as, semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element.

As used herein, “lateral,” “lateral side,” “lateral surface” refers to a side surface of an element (e.g., a layer, opening, etc.), such as a left or right-side surface in the drawings.

As used herein, “width” or “length” refers to a size of an element (e.g., a layer, trench, hole, opening, etc.) in the drawings measured from a side surface to an opposite surface of the element.

As used herein, terms such as “upper”, “lower”, “right”, “left”, “vertical”, “horizontal”, “top”, “bottom”, and derivatives thereof are to be broadly construed to relate to the disclosed structures and methods, as oriented in the drawings, wherein such structures may be understood to have the same configuration (e.g., layers stacked in the same order) even if the structure is rotated to a different angle from that shown in the drawings.

As used herein, unless otherwise specified, terms such as “on”, “overlying”, “atop”, “on top”, “positioned on” or “positioned atop” mean that a first element is present on a second element, wherein intervening elements may be present between the first element and the second element. As used herein, unless otherwise specified, the term “directly” used in connection with the terms “on”, “overlying”, “atop”, “on top”, “positioned on” or “positioned atop” or the term “direct contact” mean that a first element and a second element are connected without any intervening elements, such as, for example, intermediary conducting, insulating or semiconductor layers, present between the first element and the second element.

It is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent figures. In other instances, some processing steps or operations that are known may not be described. It should be understood that the following description is rather focused on the distinctive features or elements of the various embodiments of the present invention.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include, but are not limited to, physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s).

In the IC chip fabrication industry, there are three sections referred to in a typical IC chip build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. Accordingly, illustrative embodiments described herein may be directed to BEOL semiconductor processing and structures. BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than 10 metal layers may be added in the BEOL. The conductive contacts of the MOL layer provide electrical connections between the integrated circuitry of the FEOL layer and a first level of metallization of a BEOL structure that is formed over the FEOL/MOL layers.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

As mentioned above, static random-access memory (SRAM) may be used, for example, to temporarily store data in a computer system. The transistors in the SRAM cells may be formed from different semiconductor structures. One example is a fin-type field-effect transistor (FinFET) which is a non-planar device structure for a field-effect transistor that may be more densely packed in an integrated circuit than planar field-effect transistors. Another example is a nanosheet field-effect transistor that has been developed as an advanced type of FinFET that may permit additional increases in packing density in an integrated circuit. Thus, vertical field-effect transistors (VFETs) have become viable device options for scaling semiconductor devices (e.g., complementary metal oxide semiconductor (CMOS) devices) to 5 nanometer (nm) node and beyond.

Current SRAM circuitry can take up large amounts of space on an integrated circuit. There is a need for a high-density SRAM cell that reduces the size requirements and therefore increase the density of SRAM circuitry on an integrated circuit. VFETs, due to the flow of current vertically, have a smaller width and height compared to traditional planar field-effect transistors.

Illustrative embodiments provide methods and structures for overcoming the foregoing drawback by providing a first transistor device on a substrate in a first orientation and a second transistor device on the first transistor device in second orientation different than the first orientation, thereby shrinking the top-down cell area by around 25% to alleviate the problem of scaling down the semiconductor device.

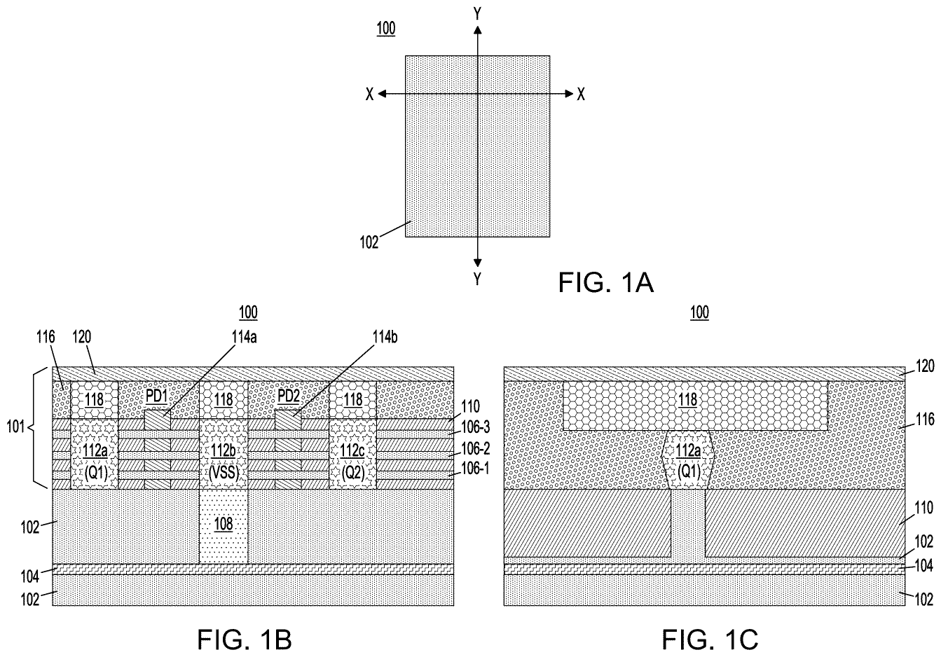

Referring now to the drawings in which like numerals represent the same of similar elements, FIGS. 1A-9 illustrate various processes for fabricating VFETs having a first transistor device on a substrate in a first orientation and a second transistor device on the first transistor device in a stacked configuration and in a second orientation different than the first orientation. Note that the same reference numeral (100) is used to denote the semiconductor structure through the various intermediate fabrication stages illustrated in FIGS. 1A-9. Note also that the semiconductor structure described herein can also be considered to be a semiconductor device and/or an integrated circuit, or some part thereof. For the purpose of clarity, some fabrication steps leading up to the production of the semiconductor structures as illustrated in FIGS. 1A-9 are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

FIG. 1A includes a top-down view of a semiconductor structure 100 containing a first transistor device 101 having a first pull-down transistor structure PD1 and a second pull-down transistor structure PD2. FIG. 1B includes a cross-sectional view of the semiconductor structure 100 containing the first transistor device 101 and FIG. 1C includes a cross-sectional view of the semiconductor structure 100 containing the first transistor device 101. The cross-sectional view of FIG. 1B is taken along the line X-X in the top-down view, and the cross-sectional view of FIG. 1C is taken along the line Y-Y in the top-down view.

The semiconductor structure 100 includes a substrate 102. The substrate 102 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. In one illustrative embodiment, the substrate 102 is silicon.

An etch stop layer 104 is formed in the substrate 102. The etch stop layer 104 may include a buried oxide (BOX) layer or silicon germanium (SiGe), or another suitable material such as a III-V semiconductor epitaxial layer.

The semiconductor structure 100 further includes the first transistor device 101 with nanosheet channel layers 106-1, 106-2 and 106-3 (collectively, nanosheet channel layers 106). The nanosheet channel layers 106 may be formed of Si or another suitable material (e.g., a material similar to that used for substrate 102).

The semiconductor structure 100 further includes a sacrificial placeholder 108 in the substrate 102. Sacrificial placeholder 108 can be composed of a sacrificial material or materials, such as SiGe, titanium oxide (TiOₓ), aluminum oxide (AlOₓ), silicon carbide (SiC), etc.

The semiconductor structure 100 further includes shallow trench isolation (STI) regions 110 on the substrate 102. The STI regions 110 may be formed of a dielectric material such as silicon dioxide (SiO₂), silicon oxycarbide (SiOC), silicon oxynitride (SiON), etc.

The first transistor device 101 of the semiconductor structure 100 further includes source/drain regions 112a, 112b and 112c that may be formed using epitaxial growth processes. The source/drain regions 112a, 112b and 112c may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl). In some embodiments, the epitaxy process includes in-situ doping (dopants are incorporated in epitaxy material during epitaxy).

Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm⁻³ to 3×10²¹ cm⁻³, or preferably between 2×10²⁰ cm⁻³ to 3×10²¹ cm⁻³.

Terms such as “epitaxial growth and/or deposition” and “epitaxially formed and/or grown” refer to the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed. For example, an epitaxial semiconductor material deposited on a {100} crystal surface will take on a {100} orientation. In some embodiments, epitaxial growth and/or deposition processes are selective to forming on a semiconductor surface, and do not deposit material on dielectric surfaces, such as silicon dioxide or silicon nitride surfaces.

Examples of various epitaxial growth processes include, for example, rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for an epitaxial deposition process can range from 500° C. to 900° C. Although higher temperature typically results in faster deposition, the faster deposition may result in crystal defects and film cracking.

A number of different sources may be used for the epitaxial growth. In some embodiments, a gas source for the deposition of epitaxial semiconductor material includes a silicon containing gas source, a germanium containing gas source, or a combination thereof. For example, an epitaxial silicon layer may be deposited from a silicon gas source including, but not necessarily limited to, silane, disilane, trisilane, tetrasilane, hexachlorodisilane, tetrachlorosilane, dichlorosilane, trichlorosilane, and combinations thereof. An epitaxial germanium layer can be deposited from a germanium gas source including, but not necessarily limited to, germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

The first transistor device 101 of the semiconductor structure 100 further includes gate structures 114a and 114b. The gate structures 114a and 114b may include a gate dielectric layer and a gate conductor layer. The gate dielectric layer may be formed of a high-k dielectric material. Examples of high-k dielectric materials include, but are not limited to, metal oxides such as HfO₂, hafnium silicon oxide (Hf-Si-O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k dielectric material may further include dopants such as lanthanum (La), aluminum (Al), and magnesium (Mg). The gate dielectric layer may have a uniform thickness.

The gate conductor layer may include a metal gate or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer as desired.

The first transistor device 101 of the semiconductor structure 100 further includes an interlevel dielectric (ILD) layer 116 formed over the gate structures 114a and 114b and source/drain regions 112a, 112b and 112c. The ILD layer 116 may be formed of any suitable isolating material, such as SiO₂, SiOC, SiON, etc.

The first transistor device 101 of the semiconductor structure 100 further includes frontside source/drain contacts 118. Suitable metals for the frontside source/drain contacts 118 include any conductive material such as, for example, a silicide liner such as Ti, Ni, NiPt, a metal adhesion layer TiN, TaN, and a conductive metal such as tungsten (W), aluminum (Al), copper (Cu), cobalt (Co), ruthenium (Ru), molybdenum (Mo), or any other suitable conductive material.

The first transistor device 101 of the semiconductor structure 100 further includes a bonding oxide layer 120. The bonding oxide layer 120 can be any suitable oxide such as SiO₂.

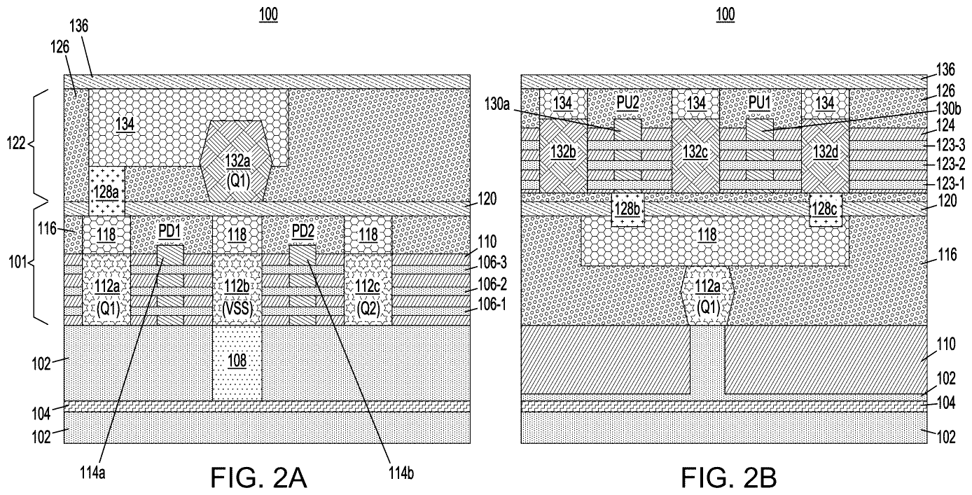

FIGS. 2A and 2B illustrate the semiconductor structure 100 following formation of a second transistor device 122 having a first pull-up transistor structure PU1 and a second pull-up transistor structure PU2 on the first transistor device 101 in a stacked configuration. The second transistor device 122 is formed having a second orientation different than the first orientation of the first transistor device 101. In some embodiments, the second transistor device 122 is formed having a second orientation of from about 85 degrees to about 95 degrees relative to the first orientation of the first transistor device 101. In some embodiments, the second transistor device 122 is formed having a second orientation of about 90 degrees relative to the first orientation of the first transistor device 101. In some embodiments, the second orientation of the second transistor device 122 is perpendicular relative to the first orientation of the first transistor device 101.

The semiconductor structure 100 further includes the second transistor device 122 with nanosheet channel layers 123-1, 123-2 and 123-3 (collectively, nanosheet channel layers 123). The nanosheet channel layers 123 may be formed of Si or another suitable material (e.g., a material similar to that used for substrate 102).

The second transistor device 122 of the semiconductor structure 100 includes STI regions 124 and an ILD layer 126. The STI regions 124 and the ILD layer 126 can be formed of a similar material as the STI regions 110 and the ILD layer 116 discussed above.

The second transistor device 122 of the semiconductor structure 100 further includes metal vias 128a, 128b and 128c in the STI regions 124 and the ILD layer 126 and through the bonding oxide layer 120 and on the frontside source/drain contact 118 contacting the source/drain region 112a of the first transistor device 101. The metal vias 128a, 128b and 128c can be formed using standard lithographic patterning and etching processes such as RIE to etch through the STI regions 124 and the ILD layer 126, the bonding oxide layer 120 and on the frontside source/drain contact 118 to form straight openings, followed by performing contact metallization by, for example, forming a silicide liner, such as Ti, Ni, or NiPt, followed by an adhesion metal liner, such as TiN, TaN, followed by a conductive metal, such as tungsten (W), aluminum (Al), copper (Cu), cobalt (Co), ruthenium (Ru), molybdenum (Mo), or any other suitable conductive material to form the metal vias 128a, 128b and 128c. In various embodiments, the conductive metal can be deposited by CVD, PVD, ALD, and/or plating. The contact metal can be planarized using, for example, a planarizing process such as CMP. Other planarization processes can include grinding and polishing.

The metal vias 128a, 128b and 128c are straight metal vias such that the metal via 128a connects a given one of the frontside source/drain contacts 118 of the first transistor device 101 with a given one of frontside source/drain contacts 134 of the second transistor device 122. The term “straight metal vias” as used herein shall be understood to mean the vertical sidewalls of the metal vias are of a uniform length from the top surface of the metal via to the bottom surface of the metal via. In addition, the metal via 128b connects a given one of the frontside source/drain contacts 118 of the first transistor device 101 with a gate structure 130a of the second pull-up transistor structure PU2 of the second transistor device 122. The metal via 128c connects a given one of the frontside source/drain contacts 118 of the first transistor device 101 with a source/drain region 132d of the first pull-up transistor structure PU1 of the second transistor device 122.

The second transistor device 122 of the semiconductor structure 100 further includes gate structures 130a and 130b. The gate structures 130a and 130b can be formed of similar material as the gate structures 114a and 114b.

The second transistor device 122 of the semiconductor structure 100 further includes source/drain regions 132a, 132b, 132c and 132d. The source/drain regions 132a, 132b, 132c and 132d can be formed of similar material as the source/drain regions 112a, 112b and 112c

The second transistor device 122 of the semiconductor structure 100 further includes frontside source/drain contacts 134. The frontside source/drain contacts 134 can be formed of similar material as the frontside source/drain contacts 118.

The second transistor device 122 of the semiconductor structure 100 further includes a bonding oxide layer 136. The bonding oxide layer 136 can be formed of similar material as the bonding oxide layer 120.

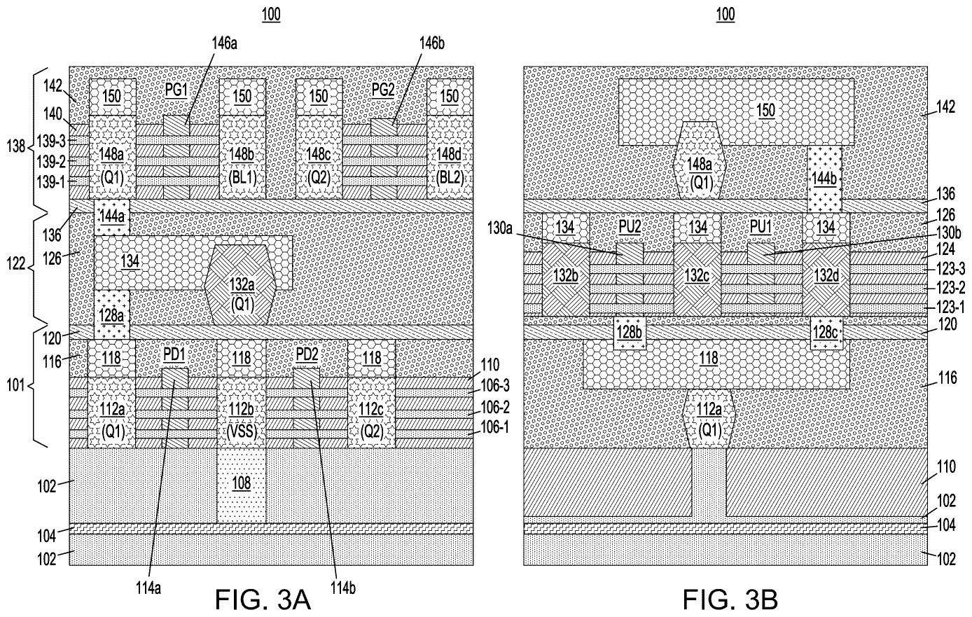

FIGS. 3A and 3B illustrate the semiconductor structure 100 following formation of a third transistor device 138 having a first pass-gate transistor structure PG1 and a second pass-gate transistor structure PG2 on the second transistor device 122 in a stacked configuration. The third transistor device 138 is formed having a third orientation different than the second orientation of the second transistor device 122. In some embodiments, the third transistor device 138 is formed having a third orientation of from about 85 degrees to about 95 degrees relative to the second orientation of the second transistor device 122. In some embodiments, the third transistor device 138 is formed having a third orientation of from about 90 degrees relative to the second orientation of the second transistor device 122. In some embodiments, the third orientation of the third transistor device 138 is perpendicular relative to the second orientation of the second transistor device 122. In some embodiments, the third transistor device 138 is formed having a third orientation that is the same as the first orientation of the first transistor device 101.

The semiconductor structure 100 further includes the third transistor device 138 with nanosheet channel layers 139-1, 139-2 and 139-3 (collectively, nanosheet channel layers 139). The nanosheet channel layers 139 may be formed of Si or another suitable material (e.g., a material similar to that used for substrate 102).

The third transistor device 138 of the semiconductor structure 100 includes STI regions 140 and an ILD layer 142. The STI regions 140 and the ILD layer 142 can be formed of a similar material as the STI regions 110 and the ILD layer 116 discussed above.

The third transistor device 138 of the semiconductor structure 100 further includes metal vias 144a and 144b in the STI regions 140 and the ILD layer 142 and through the bonding oxide layer 136 and on the frontside source/drain contact 134 contacting the source/drain region 112a of the second transistor device 122. The metal vias 144a and 144b can be formed by similar processes and of similar material as the metal vias 128a, 128b and 128c.

The metal vias 144a and 144b are straight metal vias such that the metal via 144a connects a given one of the frontside source/drain contacts 134 of the second transistor device 122 with a source/drain region 148a of the third transistor device 138. In addition, the metal via 144b connects a given one of the frontside source/drain contacts 134 of the second transistor device 122 with a given one of the frontside source/drain contacts 150 of the third transistor device 138.

The third transistor device 138 of the semiconductor structure 100 further includes gate structures 146a and 146b. The gate structures 146a and 146b can be formed of similar material as the gate structures 114a and 114b.

The third transistor device 138 of the semiconductor structure 100 further includes source/drain regions 148a, 148b, 148c and 148d. The source/drain regions 148a, 148b, 148c and 148d can be formed of similar material as the source/drain regions 112a, 112b and 112c.

The third transistor device 138 of the semiconductor structure 100 further includes frontside source/drain contacts 150. The frontside source/drain contacts 150 can be formed of similar material as the frontside source/drain contacts 118.

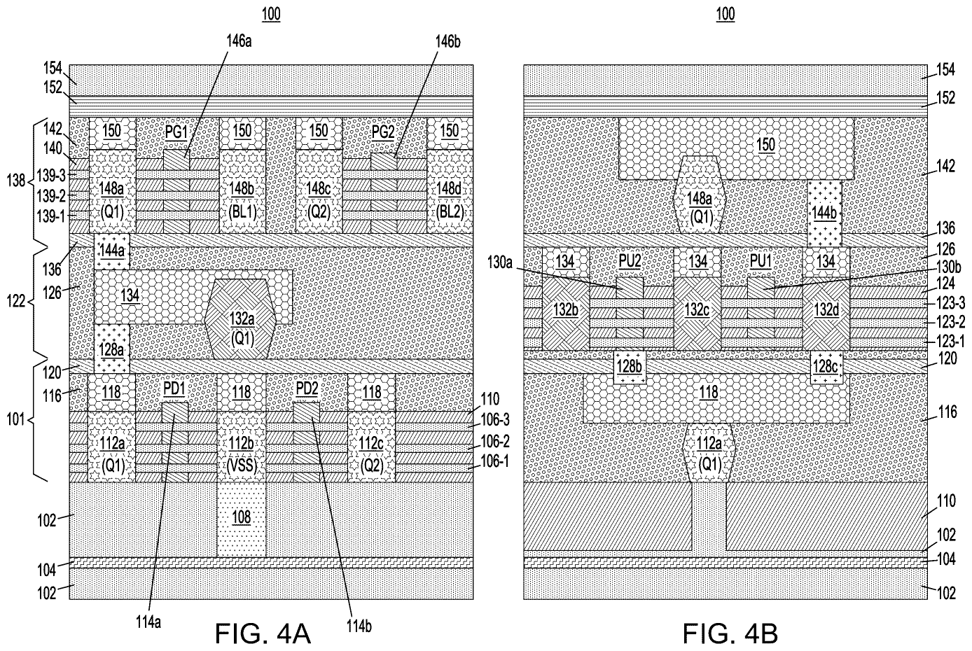

FIGS. 4A and 4B illustrate the semiconductor structure 100 following formation of a frontside BEOL interconnect 152 and a carrier wafer 154. The frontside BEOL interconnect 152 can be formed on the third transistor device 138 of the semiconductor structure 100 utilizing conventional techniques. The frontside BEOL interconnect 152 includes various BEOL interconnect structures. The carrier wafer 154 may be formed of materials similar to that of the substrate 102, and may be formed over the frontside BEOL interconnect 152 using a wafer bonding process, such as dielectric-to-dielectric bonding.

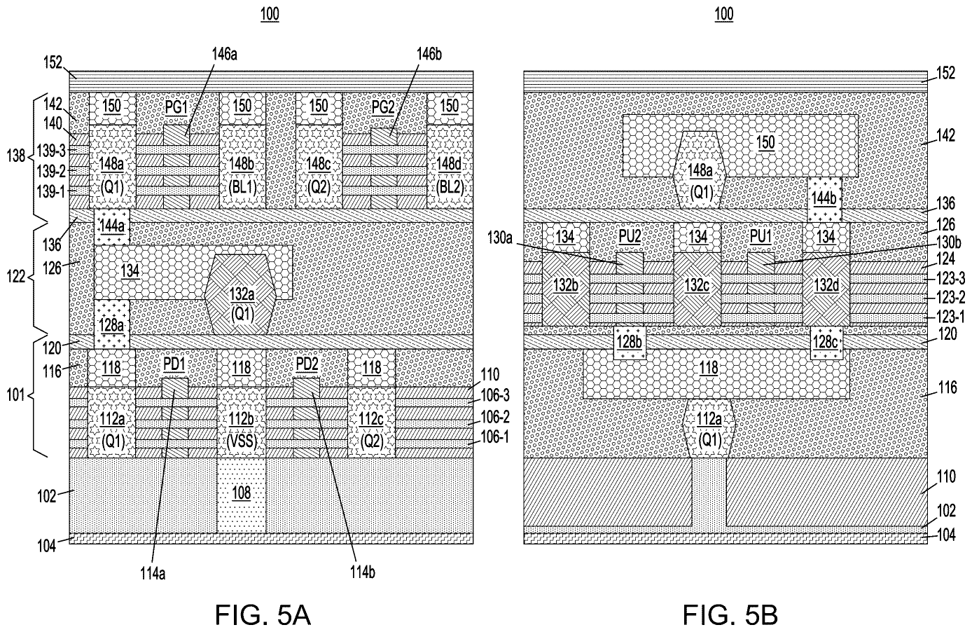

FIGS. 5A and 5B illustrate the semiconductor structure 100 following backside processing. For example, backside processing can be carried out by, for example, flipping the carrier wafer 154 over so that the backside of the substrate 102 (i.e., the back surface) is facing up for backside processing. A portion of the substrate 102, and the carrier wafer 154 may be removed from the backside using, for example, a wet etch to selectively remove the substrate 102 until the etch stop layer 104 is reached.

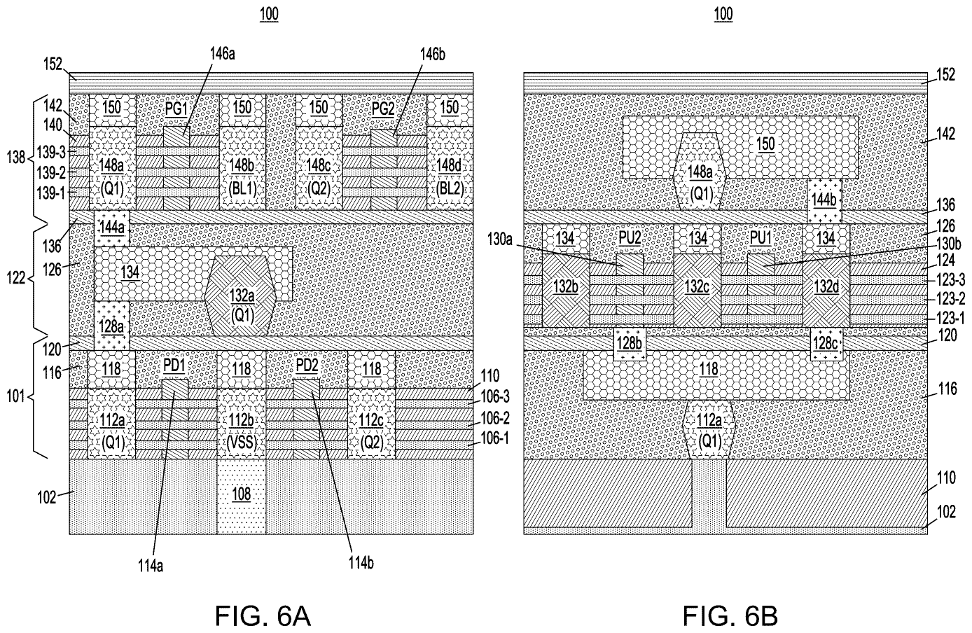

FIGS. 6A and 6B illustrate the semiconductor structure 100 following the selective removal of the etch stop layer 104. The etch stop layer 104 is selectively removed until the substrate 102 is reached. The etch stop layer 104 can be selectively removed utilizing any suitable wet or dry etching process.

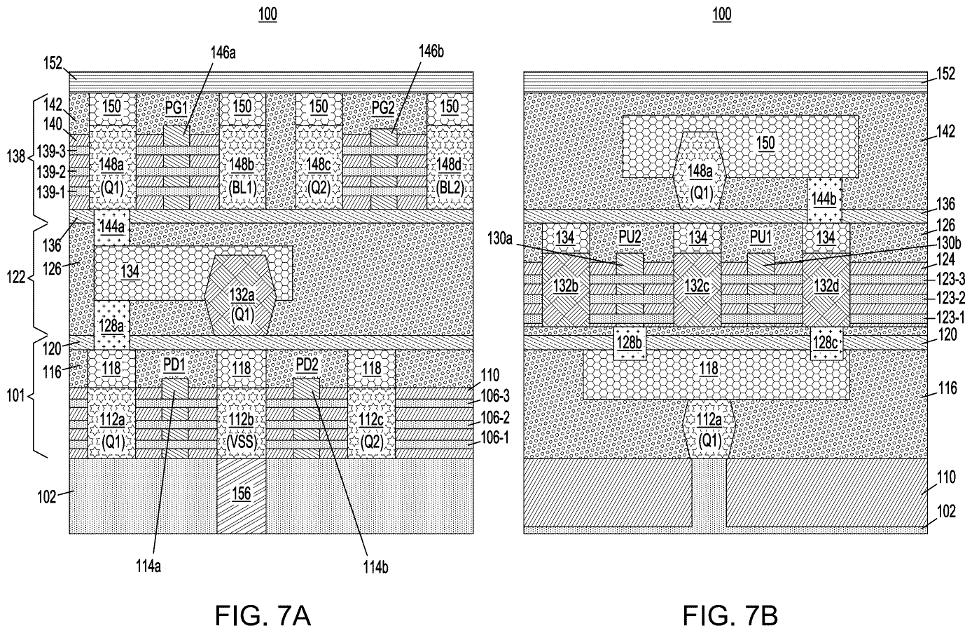

FIGS. 7A and 7B illustrate the semiconductor structure 100 following the removal of the sacrificial placeholder 108, followed by formation of backside source/drain contact 156. For example, the sacrificial placeholder 108 can be removed using any suitable etch processing that removes the sacrificial placeholder 108 selective to that of the substrate 102 to form a backside source/drain contact opening in the substrate 102. A suitable etching process includes, for example, a wet etch. The backside source/drain contact 156 can be formed by depositing a conductive metal by ALD, CVD, PVD, and/or plating. The conductive metal can be planarized using, for example, a planarizing process such as CMP. Other planarization processes can include grinding and polishing. The conductive metal for the backside source/drain contact 156 can be a similar conductive metal as the frontside source/drain contacts 118. The backside source/drain contact 156 is a VSS power source formed on the source/drain region 112b.

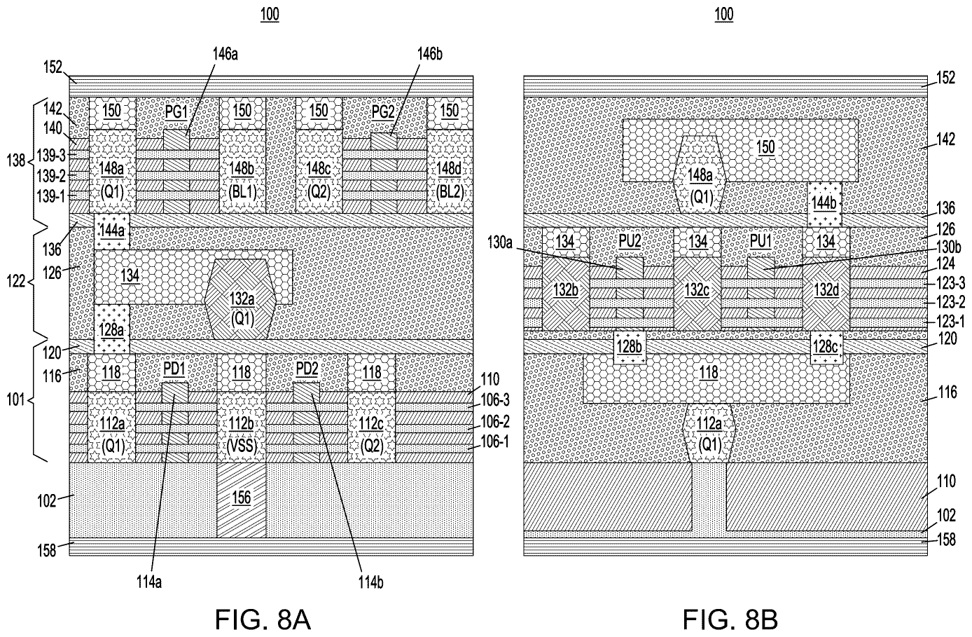

FIGS. 8A and 8B illustrate the semiconductor structure 100 following formation of a backside interconnect 158. The backside interconnect 158 is formed over the substrate 102 including the backside source/drain contact 156 and is based on creation of a wiring scheme that is disposed on both sides of the device layer (front end of line structure).

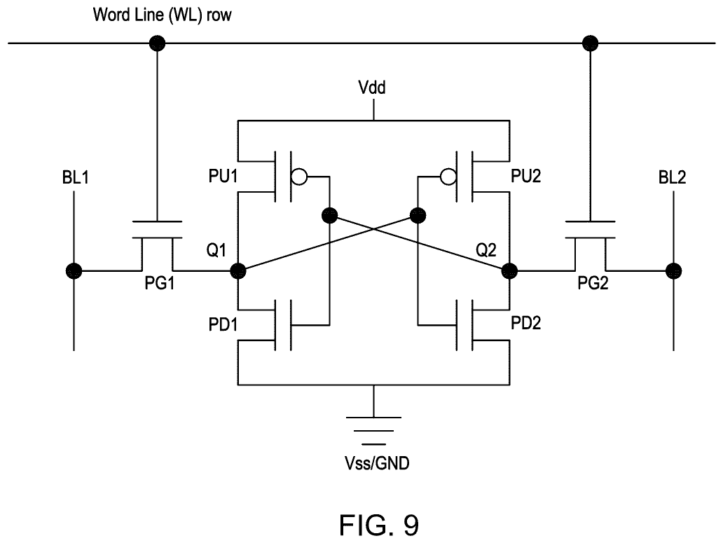

FIG. 9 shows a circuit diagram of the semiconductor structure 100. For example, the circuit shows Q1 of the second transistor device 122 connecting the source/drain region 132d of PU1 with the gate structure 130a of PU2. As another example, the circuit further shows the source/drain region 112b of the first transistor device 101 being coupled to a power source such as negative supply voltage or ground VSS.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

According to an aspect of the present disclosure, a semiconductor structure comprises a first transistor device disposed on a substrate, the first transistor device having a first orientation, and a second transistor device disposed on the first transistor device in a stacked configuration, the second transistor device having a second orientation different than the first orientation.

In non-limiting illustrative embodiments, as may be combined with one or more of the preceding paragraphs, the first transistor device comprises a first pull-down transistor structure and a second pull-down transistor structure, and the second transistor device comprises a first pull-up transistor structure and a second pull-up transistor structure.

In non-limiting illustrative embodiments, as may be combined with one or more of the preceding paragraphs, the second orientation of the second transistor device is perpendicular relative to the first orientation of the first transistor device.

In non-limiting illustrative embodiments, as may be combined with one or more of the preceding paragraphs, the semiconductor structure further comprises a third transistor device disposed on the second transistor device in a stacked configuration, the third transistor device having a third orientation different than the second orientation.

In non-limiting illustrative embodiments, as may be combined with one or more of the preceding paragraphs, the third orientation of the third transistor device is perpendicular relative to the second orientation of the second transistor device.

In non-limiting illustrative embodiments, as may be combined with one or more of the preceding paragraphs, the third orientation is a same orientation relative to the first orientation of the first transistor device.

In non-limiting illustrative embodiments, as may be combined with one or more of the preceding paragraphs, the first transistor device, the second transistor device and the third transistor device are part of a vertical static random-access memory circuit.

In non-limiting illustrative embodiments, as may be combined with one or more of the preceding paragraphs, the first transistor device further comprises a source/drain region disposed on a VSS power source, and the VSS power source is connected to a backside interconnect.

According to another aspect of the present disclosure, a semiconductor structure comprises a first transistor device disposed on a substrate, the first transistor device comprising a first source/drain region and a first frontside source/drain region contact, the first transistor device having a first orientation, a second transistor device disposed on the first transistor device in a stacked configuration, the second transistor device comprising a first transistor structure comprising a gate structure and a second transistor structure comprising a second source/drain region and a second frontside source/drain region contact, a first straight metal via connecting the first frontside source/drain region contact of the first transistor device to the gate structure, and a second straight metal via connecting the first frontside source/drain region contact of the first transistor device to the second source/drain region, wherein the second transistor device has a second orientation different than the first orientation.

In non-limiting illustrative embodiments, as may be combined with one or more of the preceding paragraphs, the first source/drain region of the first transistor device is disposed on a VSS power source, and the VSS power source is connected to a backside interconnect.

In non-limiting illustrative embodiments, as may be combined with one or more of the preceding paragraphs, the semiconductor structure further comprises a third transistor device disposed on the second transistor device in a stacked configuration, the third transistor device comprising a third source/drain region and a third frontside source/drain region contact, wherein the third transistor device has a third orientation different than the second orientation.

In non-limiting illustrative embodiments, as may be combined with one or more of the preceding paragraphs, the semiconductor structure further comprises a third straight metal via connecting the first frontside source/drain region contact to the second frontside source/drain region contact, and a fourth straight metal via connecting the second frontside source/drain region contact to the third source/drain region.

In non-limiting illustrative embodiments, as may be combined with one or more of the preceding paragraphs, the third orientation is a same orientation relative to the first orientation of the first transistor device.

In non-limiting illustrative embodiments, as may be combined with one or more of the preceding paragraphs, the first transistor device comprises a pull-down transistor device, the second transistor device comprises a pull-up transistor device and the third transistor device comprises a pass-gate transistor device.

In non-limiting illustrative embodiments, as may be combined with one or more of the preceding paragraphs, the first transistor device, the second transistor device and the third transistor device are part of a vertical static random-access memory circuit.

According to yet another aspect of the present disclosure, an integrated circuit comprises one or more semiconductor structures, wherein at least one of the one or more semiconductor structures comprises a first transistor device disposed on a substrate, the first transistor device having a first orientation, and a second transistor device disposed on the first transistor device in a stacked configuration, the second transistor device having a second orientation different than the first orientation.

In non-limiting illustrative embodiments, as may be combined with one or more of the preceding paragraphs, the first transistor device comprising a first source/drain region and a first frontside source/drain region contact; the second transistor device comprising a first transistor structure comprising a gate structure and a second transistor structure comprising a second source/drain region and a second frontside source/drain region contact; and the at least one of the one or more semiconductor structures further comprises a first straight metal via connecting the first frontside source/drain region contact of the first transistor device to the gate structure, and a second straight metal via connecting the first frontside source/drain region contact of the first transistor device to the second source/drain region.

In non-limiting illustrative embodiments, as may be combined with one or more of the preceding paragraphs, the at least one of the one or more semiconductor structures further comprises a third transistor device disposed on the second transistor device in a stacked configuration, the third transistor device comprising a third source/drain region and a third frontside source/drain region contact, wherein the third transistor device has a third orientation different than the second orientation.

In non-limiting illustrative embodiments, as may be combined with one or more of the preceding paragraphs, the at least one of the one or more semiconductor structures further comprises a third straight metal via connecting the first frontside source/drain region contact to the second frontside source/drain region contact.

In non-limiting illustrative embodiments, as may be combined with one or more of the preceding paragraphs, the at least one of the one or more semiconductor structures further comprises a fourth straight metal via connecting the second frontside source/drain region contact to the third source/drain region.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first transistor device disposed on a substrate, the first transistor device having a first orientation; and
a second transistor device disposed on the first transistor device in a stacked configuration, the second transistor device having a second orientation different than the first orientation.

2. The semiconductor structure according to claim 1, wherein the first transistor device comprises a first pull-down transistor structure and a second pull-down transistor structure, and the second transistor device comprises a first pull-up transistor structure and a second pull-up transistor structure.

3. The semiconductor structure according to claim 1, wherein the second orientation of the second transistor device is perpendicular relative to the first orientation of the first transistor device.

4. The semiconductor structure according to claim 1, further comprising:
a third transistor device disposed on the second transistor device in a stacked configuration, the third transistor device having a third orientation different than the second orientation.

5. The semiconductor structure according to claim 4, wherein the third orientation of the third transistor device is perpendicular relative to the second orientation of the second transistor device.

6. The semiconductor structure according to claim 4, wherein the third orientation is a same orientation relative to the first orientation of the first transistor device.

7. The semiconductor structure according to claim 5, wherein the first transistor device, the second transistor device and the third transistor device are part of a vertical static random-access memory circuit.

8. The semiconductor structure according to claim 1, wherein the first transistor device further comprises a source/drain region disposed on a VSS power source, and the VSS power source is connected to a backside interconnect.

9. A semiconductor structure, comprising:
a first transistor device disposed on a substrate, the first transistor device comprising a first source/drain region and a first frontside source/drain region contact, the first transistor device having a first orientation;
a second transistor device disposed on the first transistor device in a stacked configuration, the second transistor device comprising a first transistor structure comprising a gate structure and a second transistor structure comprising a second source/drain region and a second frontside source/drain region contact;
a first straight metal via connecting the first frontside source/drain region contact of the first transistor device to the gate structure; and
a second straight metal via connecting the first frontside source/drain region contact of the first transistor device to the second source/drain region;
wherein the second transistor device has a second orientation different than the first orientation.

10. The semiconductor structure according to claim 9, wherein the first source/drain region of the first transistor device is disposed on a VSS power source, and the VSS power source is connected to a backside interconnect.

11. The semiconductor structure according to claim 9, further comprising:
a third transistor device disposed on the second transistor device in a stacked configuration, the third transistor device comprising a third source/drain region and a third frontside source/drain region contact, wherein the third transistor device has a third orientation different than the second orientation.

12. The semiconductor structure according to claim 11, further comprising:
a third straight metal via connecting the first frontside source/drain region contact to the second frontside source/drain region contact; and
a fourth straight metal via connecting the second frontside source/drain region contact to the third source/drain region.

13. The semiconductor structure according to claim 11, wherein the third orientation is a same orientation relative to the first orientation of the first transistor device.

14. The semiconductor structure according to claim 11, wherein the first transistor device comprises a pull-down transistor device, the second transistor device comprises a pull-up transistor device and the third transistor device comprises a pass-gate transistor device.

15. The semiconductor structure according to claim 11, wherein the first transistor device, the second transistor device and the third transistor device are part of a vertical static random-access memory circuit.

16. An integrated circuit comprising one or more semiconductor structures, wherein at least one of the one or more semiconductor structures comprises:
a first transistor device disposed on a substrate, the first transistor device having a first orientation; and
a second transistor device disposed on the first transistor device in a stacked configuration, the second transistor device having a second orientation different than the first orientation.

17. The integrated circuit according to claim 16, wherein the first transistor device comprising a first source/drain region and a first frontside source/drain region contact; the second transistor device comprising a first transistor structure comprising a gate structure and a second transistor structure comprising a second source/drain region and a second frontside source/drain region contact; and the at least one of the one or more semiconductor structures further comprises:
a first straight metal via connecting the first frontside source/drain region contact of the first transistor device to the gate structure; and
a second straight metal via connecting the first frontside source/drain region contact of the first transistor device to the second source/drain region.

18. The integrated circuit according to claim 17, wherein the at least one of the one or more semiconductor structures further comprises a third transistor device disposed on the second transistor device in a stacked configuration, the third transistor device comprising a third source/drain region and a third frontside source/drain region contact, wherein the third transistor device has a third orientation different than the second orientation.

19. The integrated circuit according to claim 18, wherein the at least one of the one or more semiconductor structures further comprises:
a third straight metal via connecting the first frontside source/drain region contact to the second frontside source/drain region contact.

20. The integrated circuit according to claim 19, wherein the at least one of the one or more semiconductor structures further comprises:
a fourth straight metal via connecting the second frontside source/drain region contact to the third source/drain region.
